(19) United States
(12) Patent Application Publication
(10) Pub. No.: US 2007/0018189 A1
(43) Pub. Date: Jan. 25, 2007

(54) Light emitting diode

(75) Inventors: Yuan-Cheng Chin, Hsintien City (TW); Ching-Huei Wu, San Chung City (TW)

Correspondence Address: TROXELL LAW OFFICE PLLC;SUITE 1404, 5205 LEESBURG PIKE, FALLS CHURCH, VA, 22041, US

(73) Assignee: Unity Opto Technology Co., Ltd.

(21) Appl. No.: 11/186,816

(22) Filed: Jul. 22, 2005

(51) Int. Cl. H01L 29/22

(52) U.S. Cl. 257/99

(57) ABSTRACT

A light emitting diode is disclosed. A light emitting diode comprises: a bracing frame; and at least two chips stacked on the bracing frame in a chip-on-chip stacking manner. The light emitting diode for uniform color mixing is completed after each of said at least two chips is electrically connected.

### FIELD OF THE INVENTION

The present invention relates to a light emitting diode (LED) or the like for forming uniform color mixing.

### BACKGROUND OF THE INVENTION

With the progress of the LED technology, the distant prospects of the application of the white light LED are gradually shown. Nevertheless, the application of the white light LED is limited by the following factors including that it is too expensive, it has low efficiency, and it is not easy to control the color temperature. It is because that the existing white light is formed by mixing the blue light from the blue light chip with the yellow fluorescence powder. Accordingly, the application of the white light LED is affected by the conversion function of fluorescence powder. If the fluorescence powder is spread on the surface of the LED or around the LED, its uniformity and adhesion cannot be controlled effectively since it is made of inorganic polymer. Accordingly, the mixed light (white light) is not uniform. For example, the white light may have a blue-biased middle region and a yellow-biased border. When being seen by the human eyes, it may appear to be the white light. But, when being projected on a pure white paper, the shown white light may have a blue-biased middle region and a yellow-biased border.

Referring to FIG. 11, another method of manufacturing the white light LED is shown, wherein a red light chip A1, a blue light chip A2, a green light chip A3 are packaged in a package C. Besides, a control chip E is also packaged in the package C. The chips A1, A2, A3 are connected to the control chip E through leading wires B. The white light LED is connected to the environment through pins D.

However, in this structure, these chips are mounted separately. The white light is only generated on the optical overlaps of the chips. The light, which is generated on the optical border of each chip and the optical overlaps of every two chips, may have the same color as the light beam emitted from the individual chip and may be generated by mixing the light beams of every two chips. This light may be not the uniform white light. In view of this, the present inventor makes a diligent study to disclose and fabricate a light emitting diode for obtaining the uniform color mixing without increasing the production cost, wherein this light emitting diode is provided for the consumer in accordance with the motive of the present invention.

### SUMMARY OF THE INVENTION

It is a main object of the present invention to provide a light emitting diode with uniform color mixing and uniform light color.

In order to achieve the aforementioned object, a light emitting diode is disclosed. A light emitting diode comprises: a bracing frame; and at least two chips stacked on the bracing frame in a chip-on-chip stacking manner. The light emitting diode for uniform color mixing is completed after each of said at least two chips is electrically connected.

The aforementioned aspects and advantages of the present invention will be readily clarified in the description of the preferred embodiments and the enclosed drawings of the present invention.

### BRIEF DESCRIPTION OF THE DRAWINGS

FIG. 1 is a schematic localized diagram showing the preferred embodiment of present invention.

FIG. 2 is a diagram showing the first application of the first preferred embodiment of present invention.

FIG. 3 is a diagram showing the second application of the first preferred embodiment of present invention.

FIG. 4 is a diagram showing the third application of the first preferred embodiment of present invention.

FIG. 5 is a top view showing the chips of the first application of the second preferred embodiment of present invention.

FIG. 6 is a diagram showing the second application of the second preferred embodiment of present invention.

FIG. 7 is a cross-sectional diagram showing the first application of the third preferred embodiment of present invention.

FIG. 8 is a cross-sectional diagram showing the second application of the third preferred embodiment of present invention.

FIG. 9 is a schematic block diagram showing the external control IC.

FIG. 10 is a schematic block diagram showing the built-in control IC.

FIG. 11 is a top view showing a conventional white light LED.

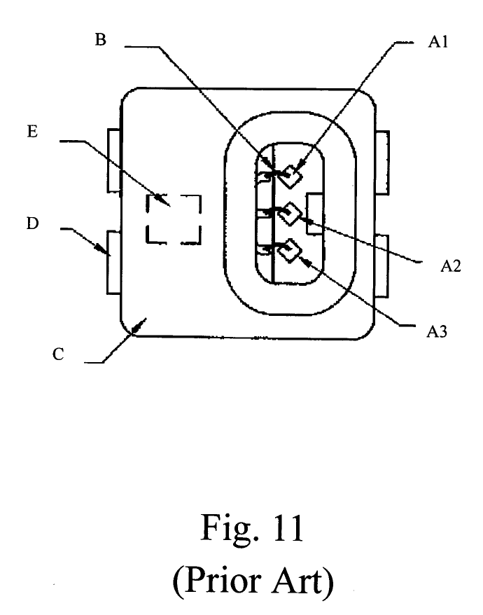

### DETAILED DESCRIPTION OF THE PREFERRED EMBODIMENT

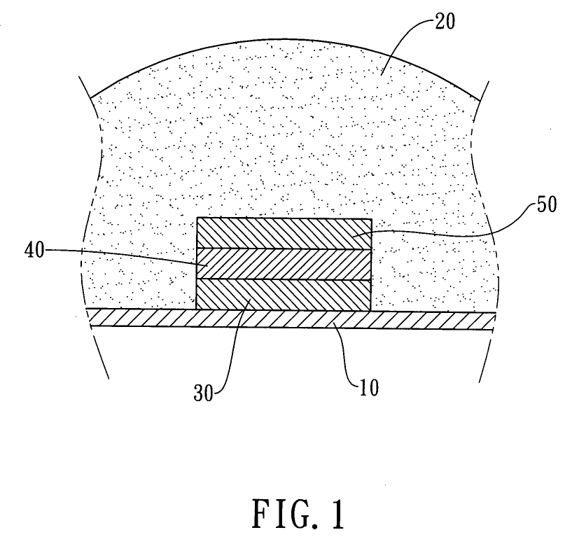

Referring to FIG. 1, a light emitting diode (LED) of the present invention comprises a bracing frame 10 for holding at least a chip and a transparent layer 20 for packaging the whole structure, wherein the bracing frame 10 is, for example, a metal frame, every kind of printed circuit board (PCB), an aluminum substrate, a ceramic substrate, or the like. In this preferred embodiment, a white light LED is illustrated for explanation. Three chips 30, 40, 50 for emitting red, green, blue lights are stacked on the bracing frame 10 in a chip-on-chip stacking manner. In other words, the chip 50 is mounted on and connected to the chip 40 by use a layer of transparent adhesive, and the chip 40 is mounted on and connected to the chip 30 by use another layer of transparent adhesive.

The stacking sequence of these chips 30, 40, 50 is not limited thereto. Besides, the stacked chips may be covered with the transparent layer 20, wherein the transparent layer 20 is made of silicone, epoxy (EP), or a composite of silicone and epoxy. Alternatively, the stacked chips may be exposed to the atmosphere directly and not covered with the transparent layer 20.

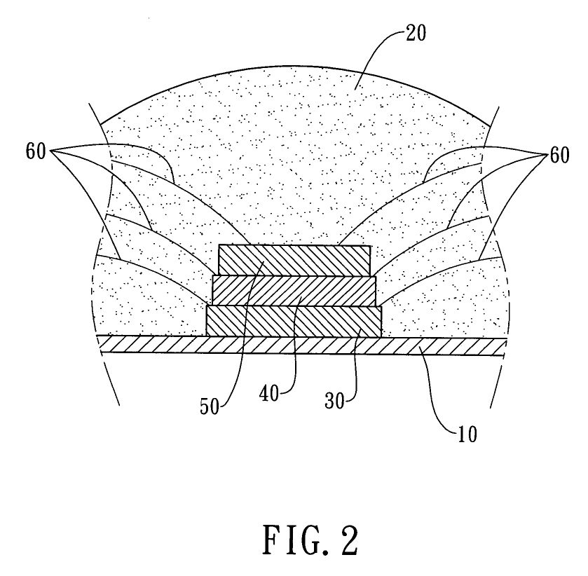

Referring to FIG. 2, each of the chips 30, 40, 50 is connected to an opposite polar frame (not shown) through a leading wire 60. Accordingly, the dimensions of the chips 30, 40, 50 are decreased gradually from bottom to top to facilitate the wire-bonding process of the leading wire 60. In other words, the dimension of the topmost chip 50 is smaller than that of the middle chip 40 so as to form a reserved region on the chip 40 for being connected to the leading wire 60. The dimension of the middle chip 40 is smaller than that of the bottommost chip 30 so as to form a reserved region on the chip 30 for being connected to the leading wire 60. Accordingly, these leading wires 60 can be respectively connected to these reserved regions, which are not overlapped with one another.

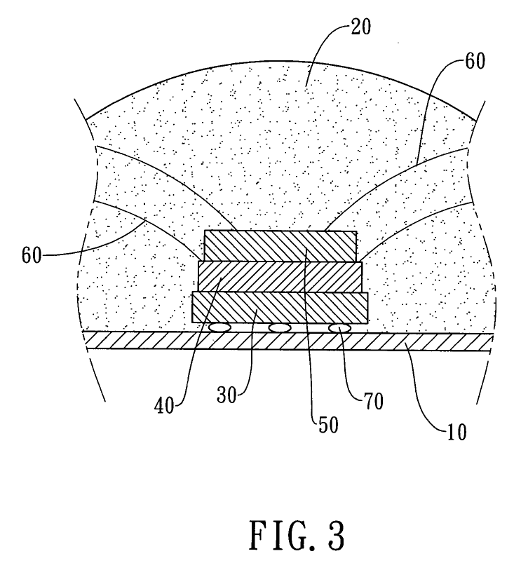

Referring to FIG. 3, the chip 30 can be connected to the bracing frame 10 by a flip-chip method that uses the tin balls or the gold balls. In this preferred embodiment, the tin balls are illustrated for explanation. The dimension of the chip 40 can be smaller than or equal to that of the chip 30. Besides, the dimension of the chip 50 must be smaller than that of the chip 40 such that the middle chip 40 and the bottommost chip 50 can be still connected to the leading wires 60, respectively.

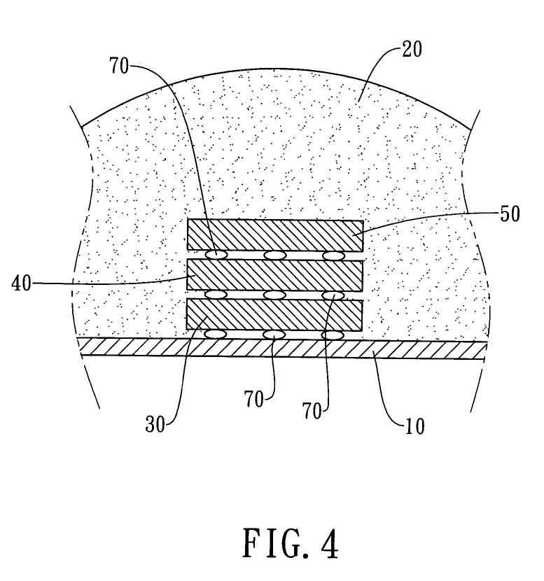

Alternatively, as shown in FIG. 4, the chip 30, 40, 50 are provided with the same dimension. These chips 30, 40, 50 are stacked in sequence by the flip-chip method. Accordingly, there is no need to utilize the wire bonding method to connect these chips 30, 40, 50 with other frames.

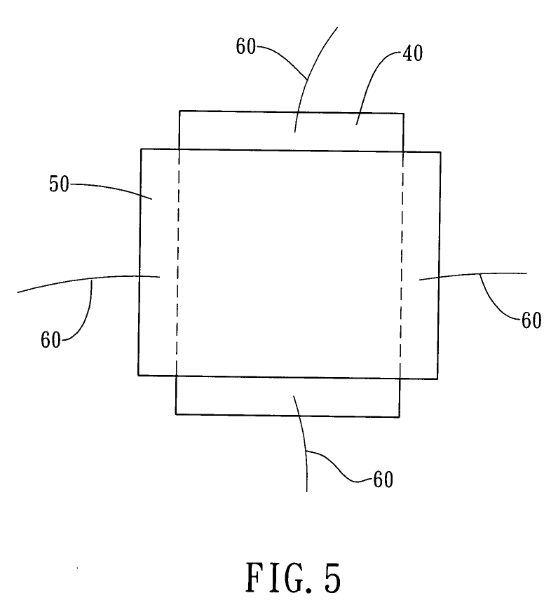

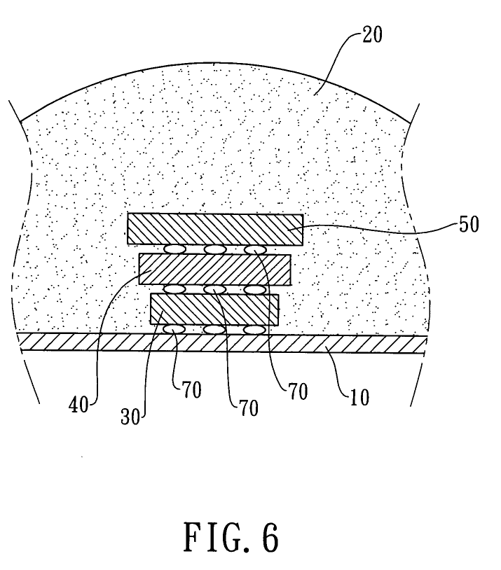

Referring to FIG. 5, the topmost chip 50 and the middle chip 40 are stacked across each other. Accordingly, the both sides of the chip 40 are extended out of the topmost chip 50 so as to form a reserved region on the chip 40 for being connected to the leading wire 60. The bottommost chip (not shown) is connected to the other frame by the flip-chip method since it is impossible to form another reserved region on the bottommost chip 30. Furthermore, as shown in FIG. 6, the middle chip 40 and the topmost chip 50 can be respectively connected the other frames by the flip-chip method that uses the tin balls 70.

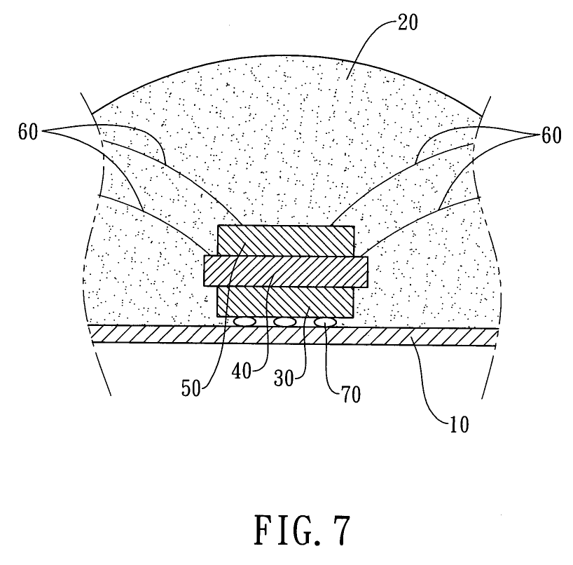

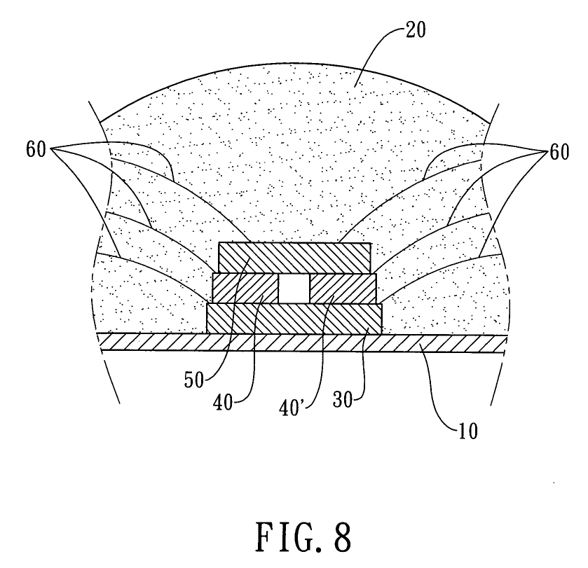

Besides, as shown in FIG. 8, two parallel chips 40, 40′ are stacked on the bottommost chip 30, and the bottommost chip 30 is mounted on the bracing frame 10, wherein a gap is formed between the chips 40, 40′. The chip 50 is then stacked on the chips 40, 40′. The profile of these chips may have a larger bottom, a larger top, or a larger middle portion (shown in FIG. 7).

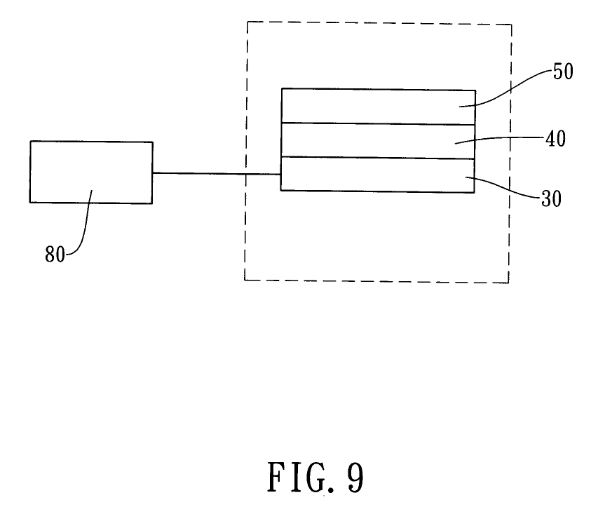

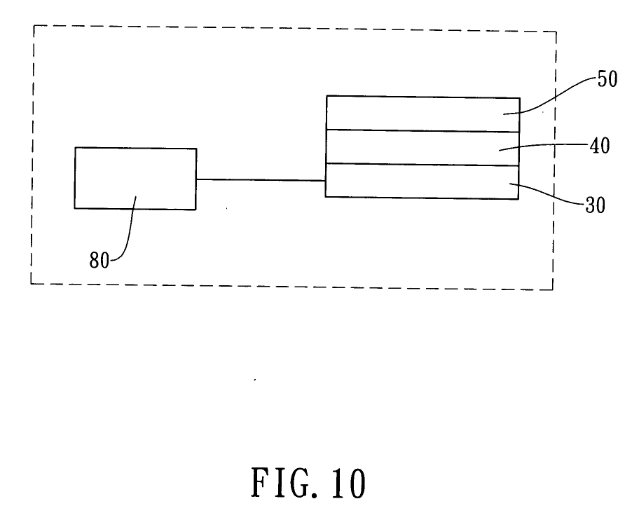

These chips 30, 40, 50 are connected to a control IC 80. Accordingly, the control IC 80 may be or may be not embedded in the package so as to form the built-in control IC 80 or the external control IC 80, as shown in FIG. 9 and FIG. 10, respectively.

On the basis of the aforementioned description, it is apparent that the structure of the present invention provides the following advantages, in which:

1. The chips for emitting different wavelengths are connected to one another by stacking so as to effectively improve the drawbacks of the conventional color mixing LED in which poor and non-uniform color mixing is generated on the optical border of each chip and the optical overlaps of every two chips.

2. The chips of the present invention are combined with one another by the connection method different from the conventional connection method so as to enlarge the scope of the optical overlap of the chips and to uniform the color mixing.

3. The light emitting diode is provided with good and uniform color mixing without increasing the production cost by merely changing the arrangement of the chips.

The light emitting diode of the present invention satisfies all requirements for a patent and is submitted for a patent.

While the preferred embodiment of the invention has been set forth for the purpose of disclosure, modifications of the disclosed embodiment of the invention as well as other embodiments thereof may occur to those skilled in the art. Accordingly, the appended claims are intended to cover all embodiments, which do not depart from the spirit and scope of the invention.

What the invention claimed is:

1. A light emitting diode comprising:
a bracing frame; and
at least two chips stacked on said bracing frame in a chip-on-chip stacking manner, wherein said light emitting diode for uniform color mixing is completed after each of said at least two chips is electrically connected.

2. The light emitting diode of claim 1, wherein said bracing frame is a metal frame, every kind of printed circuit board (PCB), an aluminum substrate, or a ceramic substrate.

3. The light emitting diode of claim 1, wherein each of said at least two chips is electrically connected by a wire bonding method.

4. The light emitting diode of claim 1, wherein each of said at least two chips is electrically connected by a flip-chip method.

5. The light emitting diode of claim 1, wherein each of said at least two chips is electrically connected by a wire bonding method and a flip-chip method.

6. The light emitting diode of claim 1, wherein said at least two chips are exposed to the atmosphere.

7. The light emitting diode of claim 1, wherein said at least two chips are covered with a transparent layer.

8. The light emitting diode of claim 7, wherein said transparent layer is made of silicone.

9. The light emitting diode of claim 7, wherein said transparent layer is made of epoxy (EP).

10. The light emitting diode of claim 7, wherein said transparent layer is made of a composite of silicone and epoxy.

11. The light emitting diode of claim 1, further comprising a built-in control IC connected to said at least two chips.

12. The light emitting diode of claim 1, further comprising an external control IC connected to said at least two chips.
